(19) United States
(12) Patent Application Publication
(10) Pub. No.: US 2022/0061196 A1
(43) Pub. Date: Feb. 24, 2022

(54) DIVERSION STRUCTURE FOR HEAT DISSIPATION OF DISPLAY CARD

(71) Applicant: TAI-SHENG HAN, New Taipei (TW)

(72) Inventor: TAI-SHENG HAN, New Taipei (TW)

(21) Appl. No.: 16/997,780

(22) Filed: Aug. 19, 2020

(51) Int. Cl. H05K 7/20; G06F 1/18; G06F 1/20

(52) U.S. Cl. CPC H05K 7/20972; G06F 1/20; G06F 1/189; G06F 1/181

(57) ABSTRACT

A diversion structure for heat dissipation of display card including a display card module, a heat dissipation module, and a backplate module. The display card module is provided with a plurality of electronic component areas, a plurality of wiring areas and a plurality of empty plate areas thereon, a plurality of guide holes are formed in the empty plate area, and the heat dissipation module is disposed on an upper side of the display card module and is provided with at least one fan and at least one heat dissipation fin set. Thereby after an airflow generated by the fan takes away the heat energy of the heat dissipation fin set, the airflow is sent toward the display card module and passes through the guide holes to be away from the display card module and the heat dissipation module.

### BACKGROUND OF THE INVENTION

### Field of Invention

The invention relates to a display card, and more particularly to a diversion structure for heat dissipation of display card capable of increasing an air output and improving a heat dissipation efficiency.

### Related Art

With the development of technology, mankind has invented more and more tools to make life more convenient. Among them, computer is the most representative invention. Through computer, people can look up information and absorb knowledge online, and can play games, listen to music and watch movies to engage in various entertainments. Computer has brought mankind into the era of information explosion and changed human lives. However, inside the computer has a display card to drive the display unit. When the display card is in operation, the display card will generate excess heat to rise the temperature of the display card. When the temperature of the display card rises, the performance of the display card will decrease or even stop operating. As shown in FIGS. 1 to 3, it is generally known that users install a heat sink 11 on a display card 1 to cool down the temperature of the display card 1. The most common heat sink 11 uses heat dissipation fins 111 to increase an area in contact with air, and fans 112 are installed on the heat dissipation fins 111 to make the air flow. But when the fans 112 generate airflow and blow toward the heat dissipation fins 111, the airflow of the fans 112 will directly blow toward the display card 1, and the airflow is completely blocked by the display card 1 to cause mutual interfering wind pressure, resulting in poor heat dissipation efficiency. Moreover, when the fans 112 generate airflow and blow toward the heat dissipation fins 111, hot air blown out will be directly blocked by the display card 1 and flow back toward both sides of the heat sink 11, causing the hot air to be sucked in by the fans 112 again. As a result, heat of the display card 1 cannot be dissipated through the heat sink 11 and there will be residual heat, which leads to poor heat dissipation efficiency of the display card 1. Moreover, the display card 1 is vertically disposed on a motherboard, when hot air flows back to both sides of the heat sink 11, the hot air will be blocked by the motherboard to form a stagnant area, causing the hot air can only be exhausted from another side opposite to the motherboard, resulting in poor heat dissipation efficiency of the display card 1.

Therefore, how to improve the drawbacks and tackle the problems mentioned above is the technical difficulty that the inventor of the invention wants to solve.

### SUMMARY OF THE INVENTION

Therefore, in order to effectively solve the above-mentioned problems, a main object of the invention is to provide a diversion structure for heat dissipation of display card capable of increasing an air output and improving a heat dissipation efficiency.

Another object of the invention is to provide a diversion structure for heat dissipation of display card capable of avoiding generating of mutual interfering wind pressure and providing a pressure relief effect.

In order to achieve the above objects, the invention provides a diversion structure for heat dissipation of display card including a display card module, a heat dissipation module, and a backplate module. Wherein the display card module is provided with a plurality of electronic component areas and a plurality of wiring areas thereon, a plurality of empty plate areas are further formed on the display card module, and a plurality of guide holes are formed in the empty plate area. The heat dissipation module is disposed on an upper side of the display card module, and the heat dissipation module is provided with at least one fan and at least one heat dissipation fin set. The backplate module is disposed on a lower side of the display card module. Thereby after an airflow generated by the fan takes away the heat energy of the heat dissipation fin set, the airflow is sent toward the display card module and passes through the guide holes to be away from the display card module and the heat dissipation module, so that the airflow is not blocked by the display card module to prevent hot air from being sucked in by the fan again, avoid the occurrence of residual heat in the display card module, and also avoid generating of mutual interfering wind pressure on the display card module and provide a pressure relief effect, and therefore achieving the efficacies of increasing an overall air output and improving a heat dissipation efficiency.

According to one embodiment of the diversion structure for heat dissipation of display card of the invention, wherein the empty plate areas are formed between the adjacent electronic component areas.

According to one embodiment of the diversion structure for heat dissipation of display card of the invention, wherein the empty plate areas are formed between the adjacent wiring areas.

According to one embodiment of the diversion structure for heat dissipation of display card of the invention, wherein the empty plate areas are formed between the adjacent electronic component areas and the wiring areas.

According to one embodiment of the diversion structure for heat dissipation of display card of the invention, wherein a plurality of through holes are formed on the backplate module.

According to one embodiment of the diversion structure for heat dissipation of display card of the invention, wherein the through hole communicates with the guide hole.

According to one embodiment of the diversion structure for heat dissipation of display card of the invention, wherein the through holes are adjacent to the guide holes.

According to one embodiment of the diversion structure for heat dissipation of display card of the invention, wherein the heat dissipation module is further provided with at least one bottom plate, and the heat dissipation module is attached to the display card module via the bottom plate.

According to one embodiment of the diversion structure for heat dissipation of display card of the invention, wherein the heat dissipation fin set communicates with the guide holes.

### BRIEF DESCRIPTION OF THE DRAWINGS

FIG. 1 is a perspective assembly view of a conventional heat sink installed on a display card;

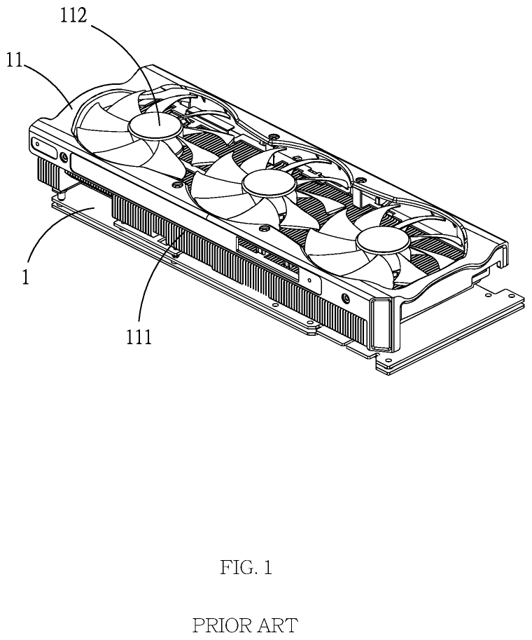

FIG. 2 is a perspective exploded view of the conventional heat sink separated from the display card;

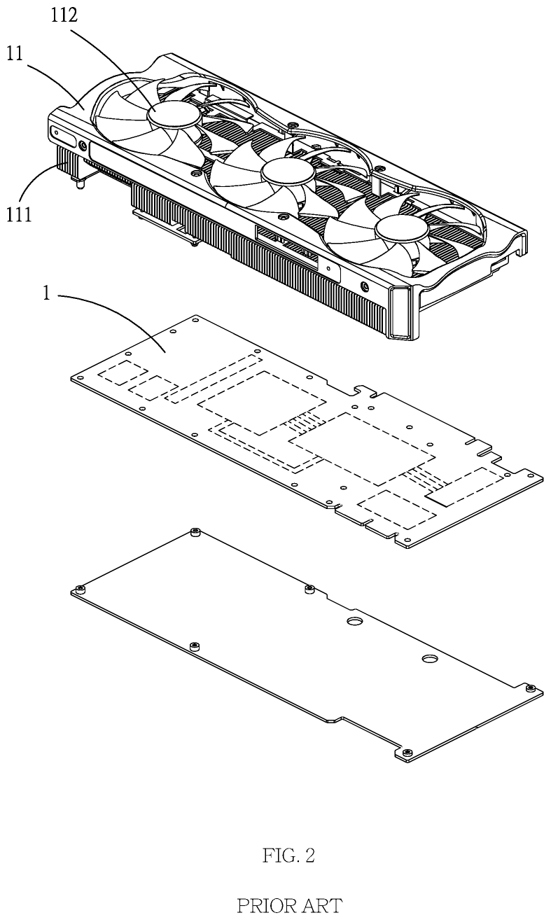

FIG. 3 is a cross-sectional view of implementation of the conventional heat sink installed on the display card;

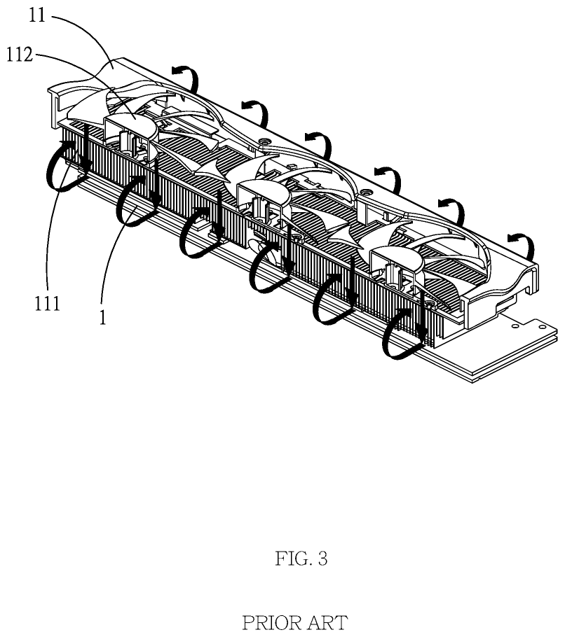

FIG. 4 is a perspective assembly view of one preferred embodiment of a diversion structure for heat dissipation of display card of the invention;

FIG. 5 is a perspective exploded view of one preferred embodiment of the diversion structure for heat dissipation of display card of the invention;

FIG. 6 is a cross-sectional view of one preferred embodiment of the diversion structure for heat dissipation of display card of the invention;

FIG. 7 is a cross-sectional view of implementation of the diversion structure for heat dissipation of display card of the invention; and

FIG. 8 is a perspective view of implementation of the diversion structure for heat dissipation of display card of the invention.

### DETAILED DESCRIPTION OF THE INVENTION

The above objects of the invention, as well as its structural and functional features, will be described in accordance with the preferred embodiments of the accompanying drawings.

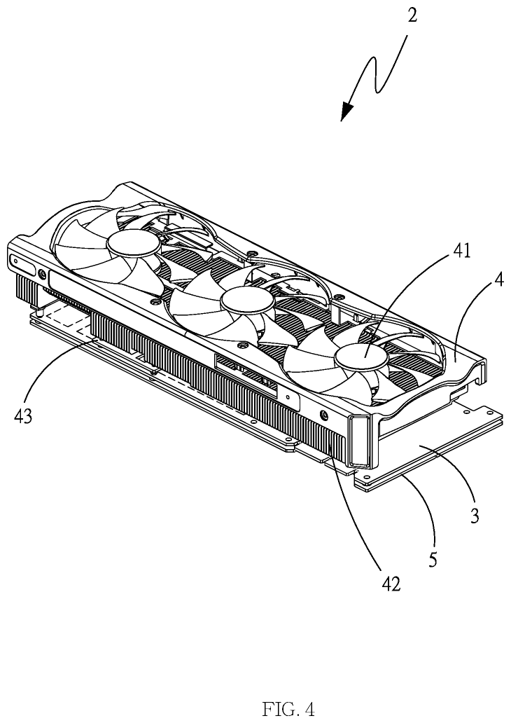

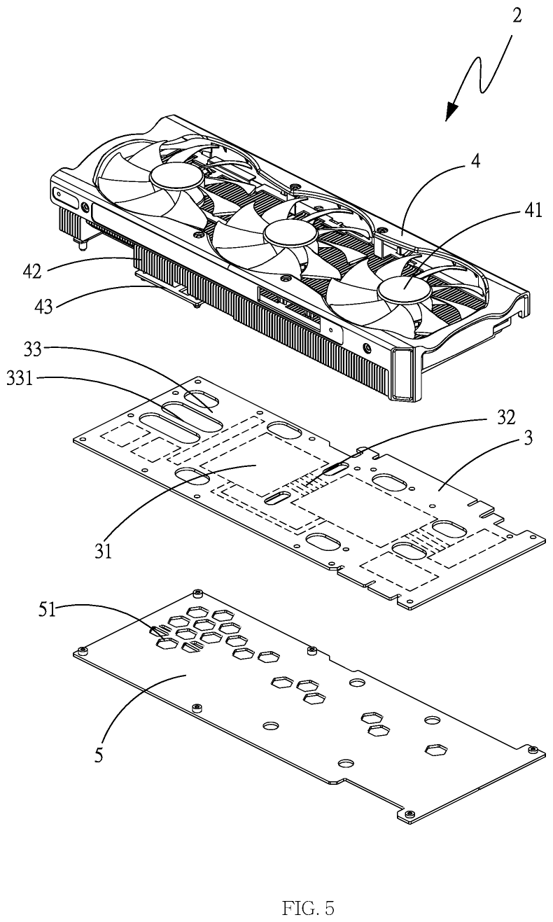

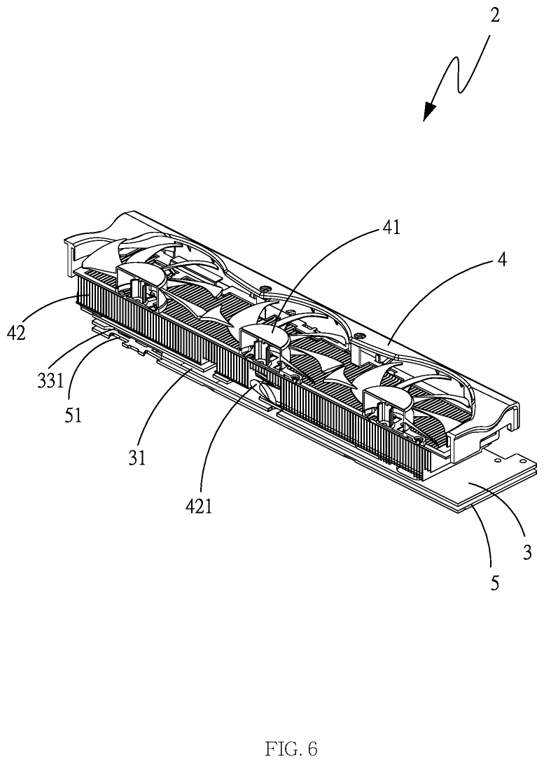

Please refer to FIGS. 4 to 6, which are perspective assembly view, perspective exploded view and cross-sectional view of one preferred embodiment of a diversion structure for heat dissipation of display card of the invention respectively. It can be clearly seen from the figures that a diversion structure for heat dissipation of display card 2 includes a display card module 3, a heat dissipation module 4, and a backplate module 5.

Wherein the display card module 3 is provided with a plurality of electronic component areas 31 and a plurality of wiring areas 32 thereon, wherein the electronic component areas 31 are provided for disposition of electronic components, and the wiring areas 32 are provided for disposition of power conducting wires. A plurality of empty plate areas 33 are further formed on the display card module 3, wherein the empty plate areas 33 can be formed between the adjacent electronic component areas 31, between the adjacent wiring areas 32, and between the adjacent electronic component areas 31 and the wiring areas 32, the empty plate areas 33 are formed with a plurality of guide holes 331 thereon, and the guide holes 331 penetrate the display card module 3.

Wherein the heat dissipation module 4 is disposed at a position on an upper side of the display card module 3, and the heat dissipation module 4 has at least one fan 41, at least one heat dissipation fin set 42 and at least one bottom plate 43. The heat dissipation module 4 is attached on the display card module 3 via the bottom plate 43, the heat dissipation fin set 42 is provided with a thermal conductive pipe 421, and the heat dissipation fin set 42 communicates with the guide holes 331.

Wherein the backplate module 5 is disposed on a lower side of the display card module 3, a plurality of through holes 51 are formed on the backplate module 5, and the through holes 51 communicate with the guide holes 331, or the through holes 51 are disposed adjacent to the guide holes 331.

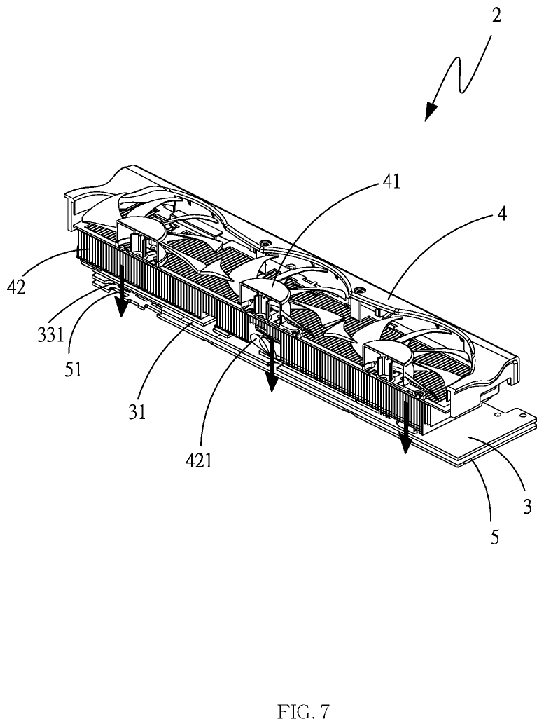

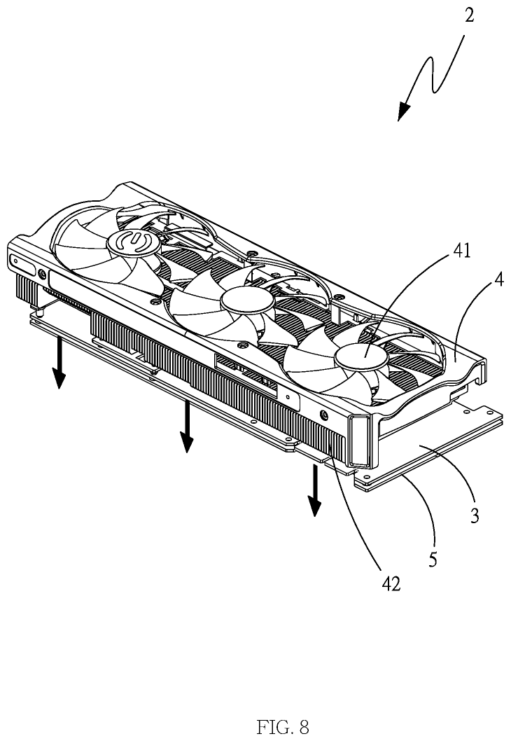

Please continue to refer to the aforementioned figures and FIGS. 7 and 8, which are cross-sectional view and perspective view of implementation of the diversion structure for heat dissipation of display card of the invention respectively. It can be clearly seen from the figures that the fan 41 generates an airflow and when the airflow is sent toward the heat dissipation fin set 42, the airflow generated by the fan 41 takes away the heat energy of the heat dissipation fin set 42, the airflow is then sent toward the display card module 3. When the airflow is sent toward the display card module 3, the airflow passes through the guide holes 331 and is sent toward another side of the display card module 3 opposite to a side facing the heat dissipation module 4, and then passes through the through holes 51, so that the airflow is away from the display card module 3 and the heat dissipation module 4, and the airflow is not blocked by the display card module 3, so as to prevent hot air from flowing back and being sucked in by the fan 41 again, avoid the occurrence of residual heat in the display card module 3, also avoid generating of mutual interfering wind pressure on the display card module 3 and provide a pressure relief effect, and therefore achieving the efficacies of increasing an overall air output and improving a heat dissipation efficiency.

It is to be understood that the above description of the preferred embodiments of the present invention is not used to limit the present invention, and changes in accordance with the concepts of the present invention may be made without departing from the spirit of the present invention, for example, the equivalent effects produced by various transformations, variations, modifications and applications made to the configurations or arrangements shall still fall within the scope covered by the appended claims of the present invention.

What is claimed is:

1. A diversion structure for heat dissipation of display card including:
a display card module, the display card module being provided with a plurality of electronic component areas and a plurality of wiring areas thereon, and a plurality of empty plate areas being formed on the display card module, a plurality of guide holes being formed in the empty plate area;
a heat dissipation module, the heat dissipation module being disposed on an upper side of the display card module, and the heat dissipation module being provided with at least one fan and at least one heat dissipation fin set; and
a backplate module, the backplate module being disposed on a lower side of the display card module.

2. The diversion structure for heat dissipation of display card as claimed in claim 1, wherein the empty plate areas are formed between the adjacent electronic component areas.

3. The diversion structure for heat dissipation of display card as claimed in claim 1, wherein the empty plate areas are formed between the adjacent wiring areas.

4. The diversion structure for heat dissipation of display card as claimed in claim 1, wherein the empty plate areas are formed between the adjacent electronic component areas and the wiring areas.

5. The diversion structure for heat dissipation of display card as claimed in claim 1, wherein a plurality of through holes are formed on the backplate module.

6. The diversion structure for heat dissipation of display card as claimed in claim 5, wherein the through hole communicates with the guide hole.

7. The diversion structure for heat dissipation of display card as claimed in claim 5, wherein the through holes are adjacent to the guide holes.

8. The diversion structure for heat dissipation of display card as claimed in claim 1, wherein the heat dissipation module is further provided with at least one bottom plate, and the heat dissipation module is attached to the display card module via the bottom plate.

9. The diversion structure for heat dissipation of display card as claimed in claim 1, wherein the heat dissipation fin set communicates with the guide holes.
